(19) United States
(12) Patent Application Publication
(10) Pub. No.: US 2006/0131582 A1
(43) Pub. Date: Jun. 22, 2006

(54) Thin film transistor array panel and manufacturing method thereof

(75) Inventors: Jae-Hong Jeon, Gyeonggi-do (KR); Jang-Soo Kim, Gyeonggi-do (KR)

Correspondence Address: DLA PIPER RUDNICK GRAY CARY US, LLP, 2000 UNIVERSITY AVENUE, E. PALO ALTO, CA, 94303-2248, US

(73) Assignee: Sansung Electronics Co., Ltd.

(21) Appl. No.: 11/271,129

(22) Filed: Nov. 10, 2005

(30) Foreign Application Priority Data
Dec. 20, 2004 (KR) 10-2004-0109056

(51) Int. Cl. H01L 29/04

(52) U.S. Cl. 257/59

(57) ABSTRACT

A thin film transistor (TFT) array panel is presented. The TFT array panel includes: a gate line formed on an insulating substrate and a gate electrode; a storage electrode line on the insulating substrate; a gate insulating layer on the gate line and the storage electrode line; a first semiconductor on the gate insulating layer; a data line and a drain electrode formed on the first semiconductor, separate from each other, and over the gate electrode; a passivation layer formed on the first semiconductor layer and having a contact hole exposing the drain electrode and an opening exposing the gate insulating layer on the storage electrode; and a pixel electrode connected to the drain electrode through the contact hole and overlapping the storage electrode through the opening.

### CROSS-REFERENCE TO RELATED APPLICATION

This patent application claims the priority of Korean Patent Application No. 10-2004-0109056 filed on Dec. 20, 2004, the content of which is incorporated by reference herein in its entirety.

### BACKGROUND OF THE INVENTION

(a) Field of the Invention

The present invention relates to a thin film transistor array panel and a manufacturing method thereof.

(b) Description of the Related Art

Liquid crystal displays (LCDs) are one of the most widely used flat panel displays today. An LCD includes two panels provided with field-generating electrodes and a liquid crystal (LC) layer interposed therebetween. The LCD displays images by applying voltages to the field-generating electrodes to generate an electric field in the LC layer, which determines orientations of LC molecules in the LC layer to adjust polarization of incident light.

Among LCDs that include field-generating electrodes on respective panels, a plurality of pixel electrodes arranged in a matrix are provided on one panel and a common electrode is provided covering an entire surface of the other panel. Images are displayed by applying individual voltages to the respective pixel electrodes. For the application of the individual voltages, a plurality of three-terminal thin film transistors (TFTs) are connected to the respective pixel electrodes, and a plurality of gate lines and a plurality of data lines are provided on the panel. The gate lines transmit signals for controlling the TFTs, and the data lines transmit voltages that are applied to the pixel electrodes. Also, a plurality of storage electrodes overlapping the pixel electrodes to form a storage capacitor are provided on the panel.

A panel for an LCD usually has a layered structure including several conductive layers and insulating layers, and several photolithography steps are required for manufacturing the LCD panel. Since the production cost increases as the number of photolithography steps increases, it is preferable to reduce the number of the photolithography steps. To reduce the production cost, the data lines and a semiconductor layer are patterned using one photoresist as an etch mask. The photoresist includes a portion having a medium thickness.

However, because the semiconductor layer remains under a conductor connected to the pixel electrodes and overlaps the storage electrodes in this manufacturing method, a flicker on the screen as well as an afterimage are generated, thereby deteriorating the characteristics of the LCD. A method of reducing the production cost without causing these undesirable side effects is desired.

### SUMMARY OF THE INVENTION

A thin film transistor array panel is provided, which includes: a gate line formed on an insulating substrate and a gate electrode; a storage electrode line on the insulating substrate; a gate insulating layer on the gate line and the storage electrode line; a first semiconductor on the gate insulating layer; a data line and a drain electrode formed on the first semiconductor, separate from each other, and over the gate electrode; a passivation layer formed on the first semiconductor and having a contact hole exposing the drain electrode and an opening exposing the gate insulating layer on the storage electrode line; and a pixel electrode connected to the drain electrode through the contact hole and overlapping the storage electrode line through the opening.

The first semiconductor, except for the portion on the gate electrode, may have the same shape as the data line and the drain electrode. The thin film transistor array panel may further include a second semiconductor at the same layer as the first semiconductor, wherein the opening extends to the second semiconductor.

The opening may be a hole that extends through the second semiconductor.

The contact hole may overlap the opening. The opening may be located inside the contact hole.

The opening may extend into the drain electrode.

The storage electrode line may be spaced apart from the gate line.

A thin film transistor array panel is provided, which includes: forming a gate line and a storage electrode line; forming a gate insulating layer covering the gate line and the storage electrode line; forming a first semiconductor and a second semiconductor overlapping the storage electrode line on the gate insulating layer; forming a data line having a source electrode and a drain electrode on the first semiconductor; forming a passivation layer having a contact hole exposing the drain electrode and an opening exposing the second semiconductor; removing the second semiconductor exposed through the opening; and forming a pixel electrode connected to the drain electrode through the contact hole. Wherein, the first and second semiconductors, the data line, and the drain electrode are formed by photolithography using one photoresist film as an etch mask.

The photoresist film may include a first portion corresponding to a channel area on the portion between the source electrode and the drain electrode, and a storage area corresponding to a portion of the storage electrode line, and a second portion corresponding to a wire area on the data line and the drain electrode.

The photoresist film may be formed by photolithography using one mask.

The method may further include forming an ohmic contact layer between the first and second semiconductors and the data line and drain electrode.

The formation of the data line and drain electrode, the ohmic contact layer, and the first and second semiconductors may include: depositing a silicon layer, a doped silicon layer, and a conductor layer; forming a photoresist film including a first portion corresponding to a channel area on the portion between the source electrode and the drain electrode, a storage area corresponding to a portion of the storage electrode line, and a second portion corresponding to a wire area on the data line and the drain electrode; etching the conductor layer corresponding to a remaining area except for the storage, wire, and channel areas; etching the silicon layer and the doped silicon layer on the remaining area; removing the first portion to expose the conductor layer on the storage and channel areas; etching the conductor layer and the doped silicon layer on the storage and channel areas; and removing the second portion.

### BRIEF DESCRIPTION OF THE DRAWINGS

The above and other advantages of the present invention will become more apparent by describing preferred embodiments thereof in detail with reference to the accompanying drawings, in which:

FIG. 1 is a layout view of a TFT array panel for an LCD according to an embodiment of the present invention;

FIGS. 2 and 3 are sectional views of the TFT array panel shown in FIG. 1 taken along the lines II-II′ and III-III′, respectively;

FIG. 4 is a layout view of the TFT array panel shown in FIGS. 1-3 in the first step of a manufacturing method thereof according to an embodiment of the present invention;

FIGS. 5A and 5B are sectional views of the TFT array panel shown in FIG. 4 taken along the lines VA-VA′ and VB-VB′, respectively;

FIGS. 6A and 6B are sectional views of the TFT array panel shown in FIG. 4 taken along the lines VA-VA′ and VB-VB′, respectively, and illustrate the step following the step shown in FIGS. 5A and 5B;

FIGS. 7A and 7B are sectional views of the TFT array panel shown in FIG. 4 taken along the lines VA-VA′ and VB-VB′, respectively, and illustrate the step following the step shown in FIGS. 6A and 6B;

FIG. 8 is a layout view of the TFT array panel in the step following the step shown in FIGS. 7A and 7B;

FIGS. 9A and 9B are sectional views of the TFT array panel shown in FIG. 8 taken along the lines IXA-IXA′ and IXB-IXB′, respectively;

FIG. 10 is a layout view of the TFT array panel in the step following the step shown in FIGS. 9A and 9B;

FIGS. 11A and 11B are sectional views of the TFT array panel shown in FIG. 10 taken along the lines XIA-XIA′ and XIB-XIB′, respectively;

FIG. 12 is a layout view of a TFT array panel of an LCD according to another embodiment of the present invention;

FIG. 13 is a layout view of a common electrode panel of an LCD according to an embodiment of the present invention;

FIG. 14 is a layout view of an LCD including the TFT array panel shown in FIG. 12 and the common electrode panel shown in FIG. 13;

FIG. 15 is a sectional view of the LCD shown in FIG. 14 taken along the line XV-XV′;

FIG. 16 is a layout view of a TFT array panel of an LCD according to another embodiment of the present invention;

FIG. 17 is a layout view of a common electrode panel of an LCD according to an embodiment of the present invention;

FIG. 18 is a layout view of an LCD including the TFT array panel shown in FIG. 16 and the common electrode panel shown in FIG. 17; and

FIG. 19 is a sectional view of the LCD shown in FIG. 18 taken along the line XIX-XIX′.

### DETAILED DESCRIPTION OF THE EMBODIMENTS

The present invention will be described more fully hereinafter with reference to the accompanying drawings, in which preferred embodiments of the invention are shown. The present invention may, however, be embodied in many different forms and should not be construed as limited to the embodiments set forth herein.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present.

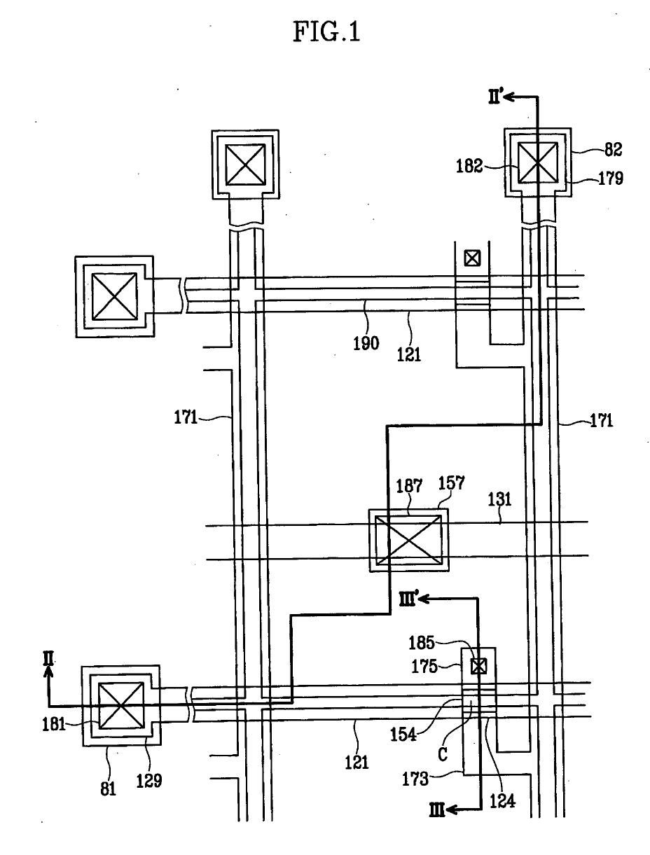

Now, a TFT array panel for an LCD will be described in detail with reference to FIGS. 1 to 3.

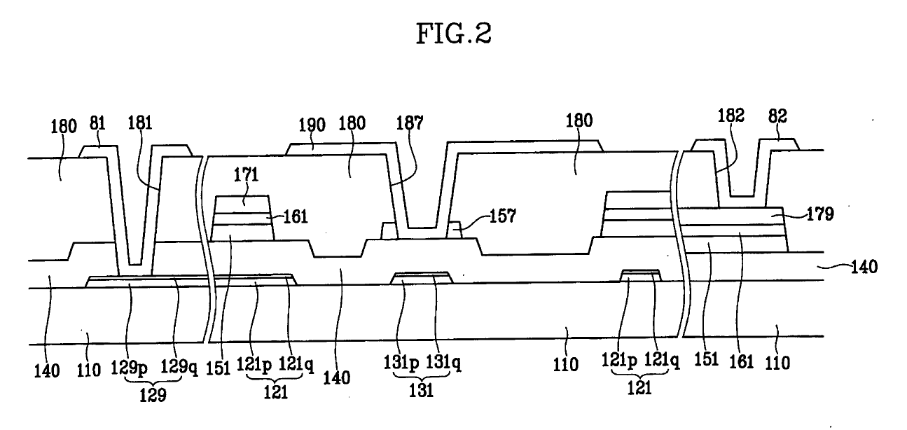

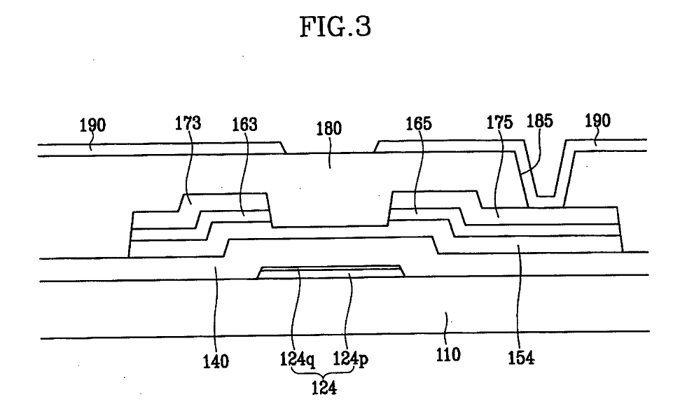

FIG. 1 is a layout view of a TFT array panel for an LCD according to an embodiment of the present invention, and FIGS. 2 and 3 are sectional views of the TFT array panel shown in FIG. 1 taken along the lines II-II′ and III-III′, respectively.

A plurality of gate lines 121 and a plurality of storage electrode lines 131 are formed on an insulating substrate 110, such as transparent glass.

The gate lines 121 extend substantially in a first direction, separate from each other, and transmit gate signals. Each gate line 121 includes a plurality of projections forming a plurality of gate electrodes 124 and an end portion 129 having a large area for contact with another layer or an external driving circuit. The gate lines 121 may extend to be connected to a driving circuit that may be integrated on the insulating substrate 110.

Each of the storage electrode lines 131, which are separated from the gate lines 121, extends substantially in the same direction as the gate lines 121 and is disposed between two gate lines 121. The storage electrode lines 131 are supplied with a predetermined voltage such as the common voltage of the other panel (not shown). The storage electrode lines 131 may include a plurality of expansions having a large area.

The gate lines 121 and the storage electrode lines 131 are preferably made of an Al-containing metal such as Al and Al alloy, an Ag-containing metal such as Ag and Ag alloy, a Cu-containing metal such as Cu and Cu alloy, a Mo-containing metal such as Mo and Mo alloy, Cr, Ti, or Ta. As shown in FIG. 2, the gate lines 121 include two films having different physical characteristics, a lower film 121p and an upper film 121q. The upper film 121q is preferably made of a low resistivity metal including an Al-containing metal, such as Al and Al alloy, for reducing signal delay or voltage drop in the gate lines 121, and has a thickness in the range of 1,000-3,000 Å. On the other hand, the lower film 121p is preferably made of a material such as Cr, Mo, and Mo alloy, which has good physical, chemical, and electrical contact characteristics with other materials such as indium tin oxide (ITO) and indium zinc oxide (IZO) and has a thickness in the range of 100-1,000 Å. A good exemplary combination of the lower film material and the upper film material is Mo and Al—Nd alloy. Their positions may be exchangeable. In FIGS. 2 and 3, the lower and upper films of the gate electrodes 124 are indicated by reference numerals 124p and 124q, respectively, the lower and upper films of the end positions 129 are indicated by reference numerals 129p and 129q, respectively, and the lower and upper films of the storage electrode lines 131 are indicated by reference numerals 131p and 131q, respectively. Portions of the upper film 129q of the end portions 129 of the gate lines 121 may be removed to expose the underlying portions of the lower films 129p.

In addition, the lateral sides of the upper films 121q, 124q, 129q, and 131q, and the lower films 121p, 124p, 129p, and 131p are tapered to form an angle of about 30-80 degrees with respect to a surface of the substrate 110.

A gate insulating layer 140 preferably made of silicon nitride (SiNx) is formed on the gate lines 121.

A plurality of semiconductor stripes 151 and a plurality of semiconductor islands 157, preferably made of hydrogenated amorphous silicon (abbreviated to “a-Si”), are formed on the gate insulating layer 140. Each semiconductor stripe 151 extends substantially in a second direction that is substantially perpendicular to the first direction and has a plurality of projections 154 branched out toward the gate electrodes 124. Each semiconductor island 157 is disposed on the storage electrode lines 131, and has an opening (e.g., a hole) disposed within the boundary of the semiconductor island 157.

A plurality of ohmic contact stripes and islands 161 and 165, preferably made of silicide or n+ hydrogenated a-Si heavily doped with n-type impurity, are formed on the semiconductor stripes 151. Each ohmic contact stripe 161 has a plurality of projections 163, and the projections 163 and the ohmic contact islands 165 are located in pairs on the projections 154 of the semiconductor stripes 151.

The lateral sides of the semiconductor stripes 151 and the ohmic contacts 161 and 165 are tapered to form angles of between about 30-80 degrees with respect to a surface of the substrate 110.

A plurality of data lines 171 and a plurality of drain electrodes 175 are formed on the ohmic contacts 161 and 165.

The data lines 171 for transmitting data voltages extend substantially in the longitudinal direction and intersect the gate lines 121. A plurality of branches of each data line 171 that project toward the drain electrodes 175 form a plurality of source electrodes 173. Each pair of source electrodes 173 and drain electrodes 175 are separated from each other and positioned across a gate electrode 124 from each other. A gate electrode 124, a source electrode 173, and a drain electrode 175, along with a projection 154 of a semiconductor stripe 151, form a TFr having a channel formed in the projection 154 disposed between the source electrode 173 and the drain electrode 175.

The data lines 171 and drain electrodes 175 are also preferably made of an Al-containing metal such as Al and Al alloy, an Ag-containing metal such as Ag and Ag alloy, a Cu-containing metal such as Cu and Cu alloy, a Mo-containing metal such as Mo and Mo alloy, Cr, Ti, or Ta, and may have a single-layered or multi-layered structure.

Like the gate lines 121, the data lines 171 and drain electrodes 175 have tapered lateral sides that form angles of about 30-80 degrees with respect to the substrate 110.

The ohmic contacts 161 and 165 are interposed only between the underlying semiconductor stripes 151 and the overlying data lines 171. The ohmic contact 161 reduces the contact resistance between the semiconductor stripes 151 and the data lines 171, and the ohmic contact 165 is covered by the drain electrodes 175. Also, the semiconductor stripes 151 of the TFT array panel according to this embodiment have almost the same planar shapes as the data lines 171 and the drain electrodes 175 as well as the underlying ohmic contacts 161 and 165. However, the projections 154 of the semiconductor stripes 151 include some exposed portions, which are not covered with the data lines 171 and the drain electrodes 175, such as portions located between the source electrodes 173 and the drain electrodes 175.

A passivation layer 180 is formed on the data lines 171, the drain electrodes 175, and the exposed portions of the semiconductor stripes 151. The passivation layer 180 is preferably made of an inorganic insulator such as silicon nitride or silicon oxide, a photosensitive organic material having a good flatness characteristic, or a low dielectric insulating material such as a-Si:C:O and a-Si:O:F formed by plasma enhanced chemical vapor deposition (PECVD). The passivation layer 180 may have a double-layered structure including a lower inorganic film and an upper organic film.

The passivation layer 180 has a plurality of contact holes 185 and 182 exposing the drain electrodes 175, and end portions 179 of the data lines 171, respectively. The passivation layer 180 and the gate insulating layer 140 have a plurality of contact holes 182 exposing end portions 129 of the gate lines 121. Furthermore, the passivation layer 180 has a plurality of openings 187 exposing the gate insulating layer 140 on the storage electrode lines 131 along with the openings of the semiconductor islands 157.

A plurality of pixel electrodes 190 and a plurality of contact assistants 81 and 82, which are preferably made of IZO or ITO, are formed on the passivation layer 180.

The pixel electrodes 190 are physically and electrically connected to the drain electrodes 175 through the contact holes 185 such that the pixel electrodes 190 receive the data voltages from the drain electrodes 175.

Referring back to FIG. 2, the pixel electrodes 190 supplied with the data voltages generate electric fields in cooperation with the common electrode on the other panel (not shown), which reorient the liquid crystal molecules in the liquid crystal layer 3 disposed therebetween.

As described above, a pixel electrode 190 and a common electrode form a liquid crystal capacitor, which stores applied voltages after turn-off of the TFr Q. An additional capacitor called a “storage capacitor,” which is connected in parallel to the liquid crystal capacitor, is provided for enhancing the voltage storing capacity. The storage capacitors are implemented by overlapping the pixel electrodes 190 with the gate lines 121 adjacent thereto (called “previous gate lines”) or the storage electrode lines 131.

As mentioned above, the undesirable flicker on the screen and the afterimage are caused by the semiconductor layer being under a conductor that is connected to the pixel electrodes and overlapping the storage electrodes. In the embodiment according to the present invention, the gate insulating layer 140, as a dielectric of the storage capacitor, is disposed between the pixel electrode 190 and the storage electrode lines 131, thus providing a uniform storage capacitance. This way, the storage capacitance may be maximized in the optimized area. Accordingly, a flicker on the screen, as well as an afterimage, is prevented and the characteristics of the LCD is enhanced.

In a different embodiment, the opening 187 of the passivation layer 180, which exposes the gate insulating layer 140, may be disposed on the previous gate lines 121 by overlapping the pixel electrodes 190 with the gate lines 121 adjacent thereto to form a storage capacitor. In this embodiment, the gate lines 121 may be extended so that they are overlaid by the pixel electrodes 190.

Optionally, the pixel electrodes 190 may overlap the gate lines 121 and the data lines 171 to increase an aperture ratio.

The contact assistants 81 and 82 are connected to the exposed end portions 129 of the gate lines 121 and the exposed end portions 179 of the data lines 171 through the contact holes 181 and 182, respectively. The contact assistants 81 and 82 are not requisites but are preferred to protect the exposed portions 129 and 179 and to complement the adhesiveness of the exposed portion 129 and 179 with external devices.

According to another embodiment of the present invention, the pixel electrodes 190 are made of a transparent conductive polymer. For a reflective LCD, the pixel electrodes 190 are made of an opaque reflective metal. In these cases, the contact assistants 81 and 82 may be made of a material, such as IZO or ITO, different from the pixel electrodes 190.

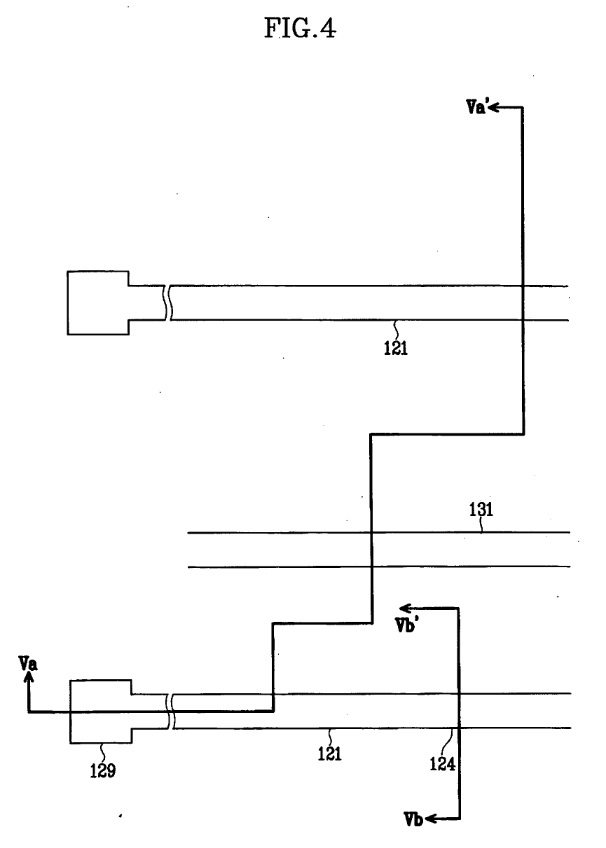

A method of manufacturing the TFT array panel shown in FIGS. 1 to 3 according to an embodiment of the present invention will now be described in detail with reference to FIGS. 4 to 11B as well as FIGS. 1 to 3.

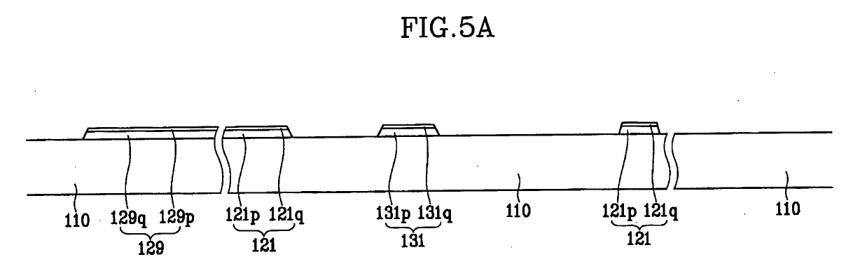

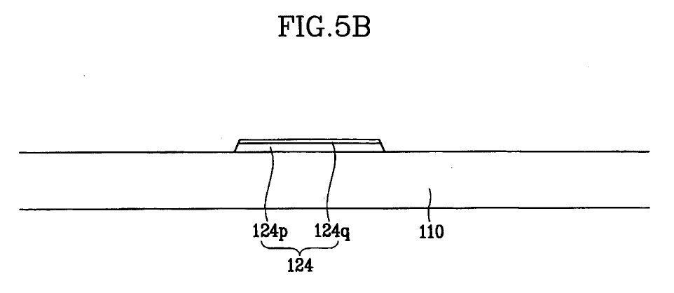

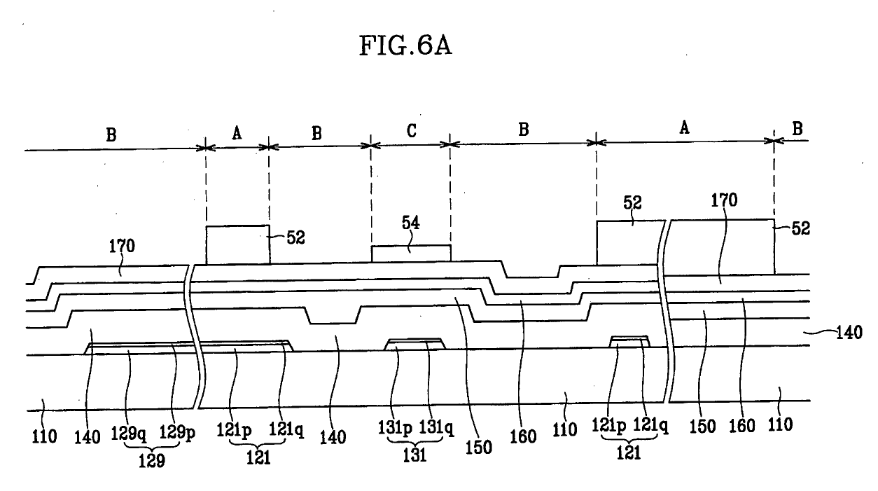

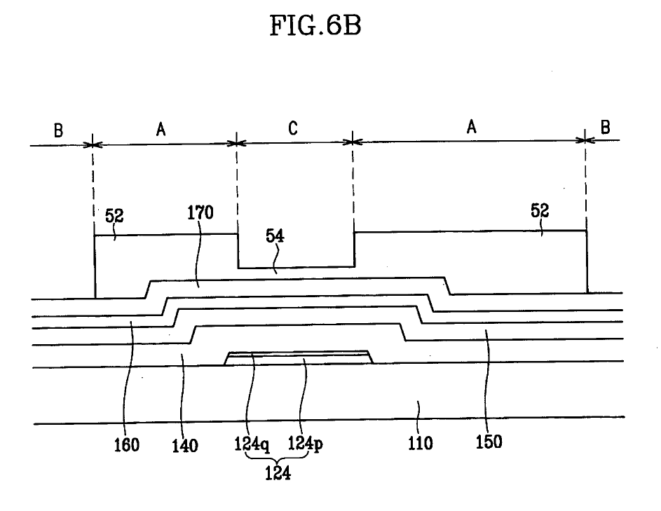

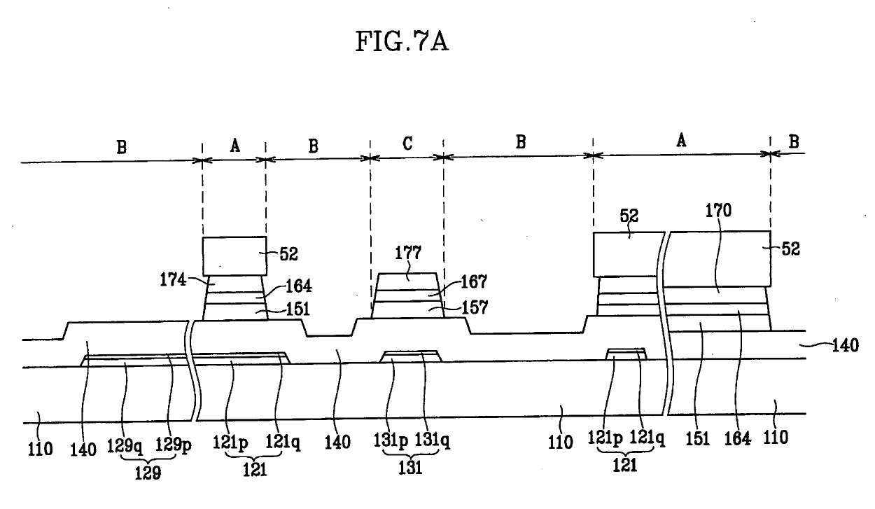

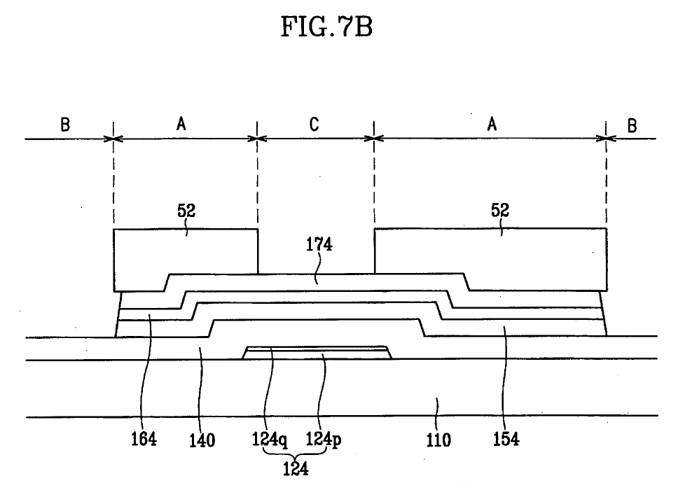

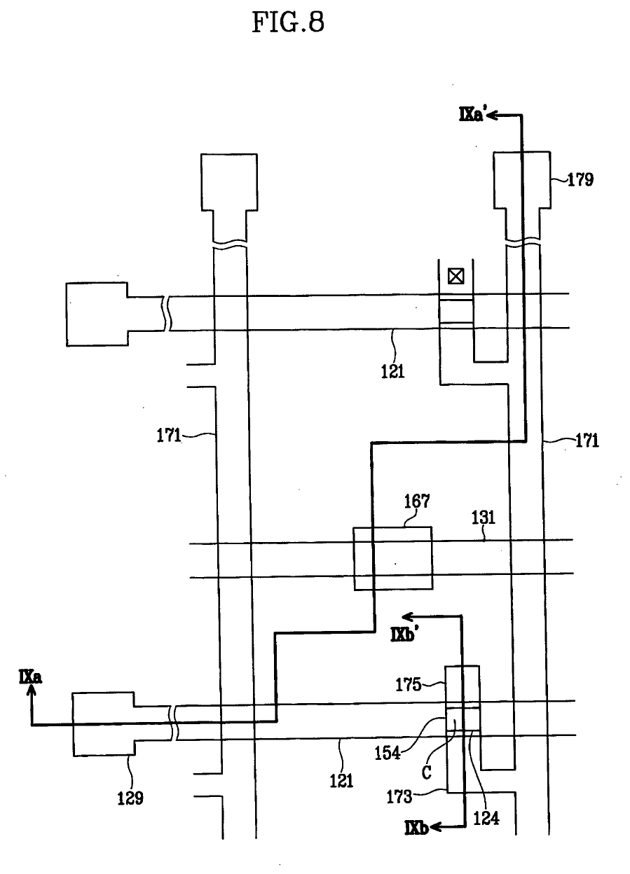

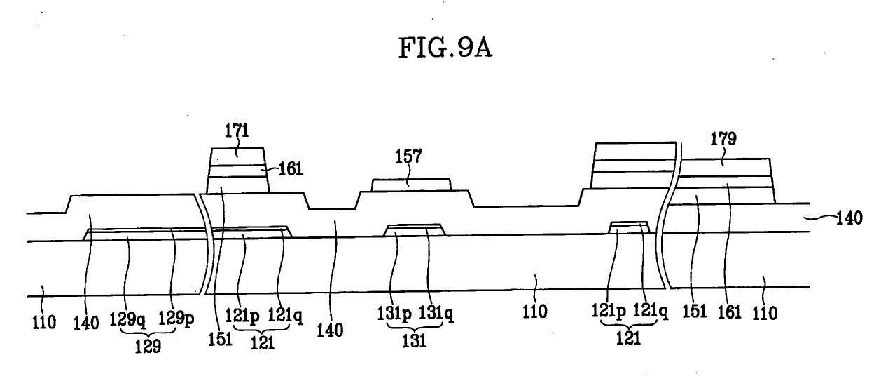

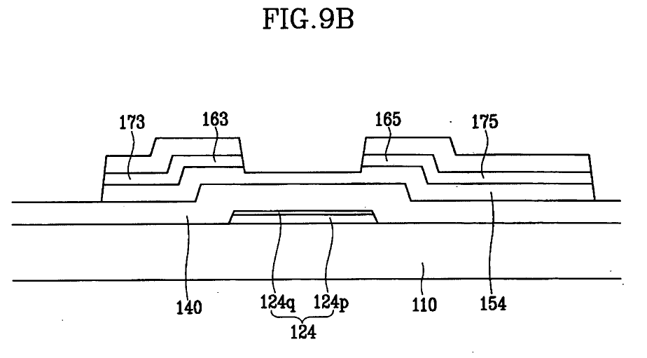

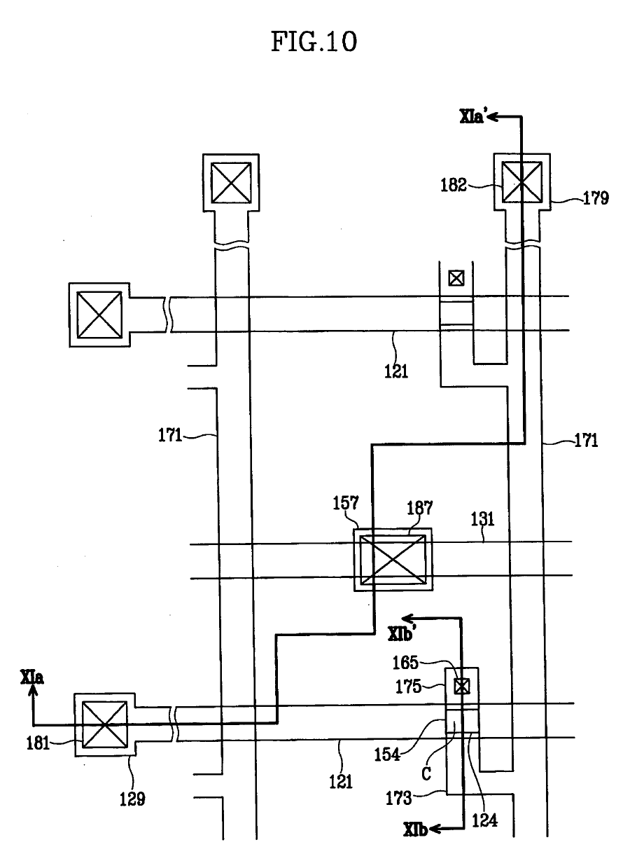

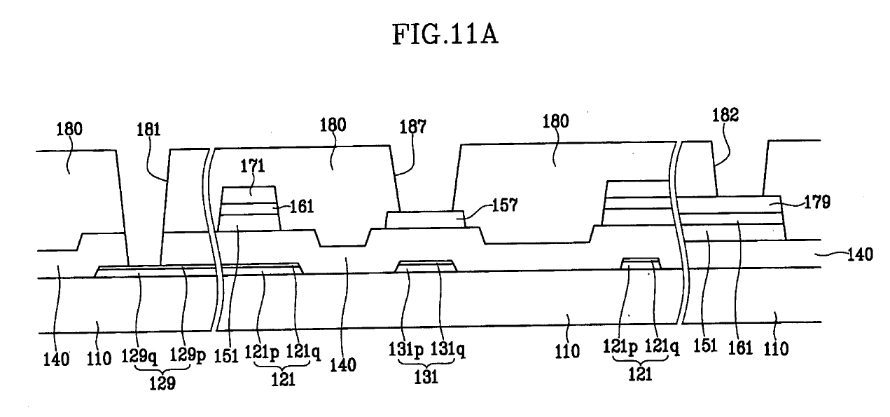

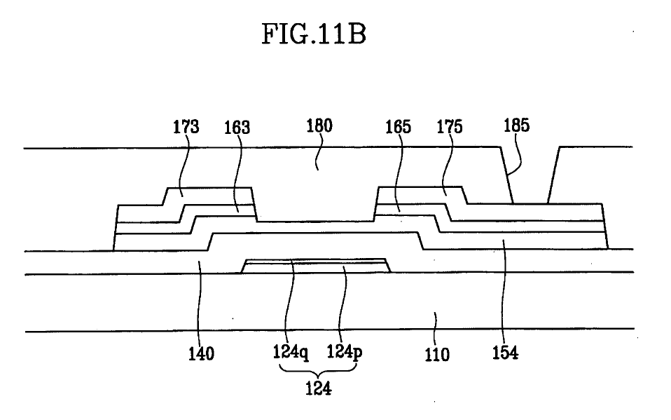

FIG. 4 is a layout view of the TFT array panel shown in FIGS. 1-3, in the first step of a manufacturing method thereof according to an embodiment of the present invention; FIGS. 5A and 5B are sectional views of the TFT array panel shown in FIG. 4 taken along the lines VA-VA′ and VB-VB′, respectively; FIGS. 6A and 6B are sectional views of the TFT array panel shown in FIG. 4 taken along the lines VA-VA′ and VB-VB′, respectively, and illustrate the step following the step shown in FIGS. 5A and 5B; FIGS. 7A and 7B are sectional views of the TFT array panel shown in FIG. 4 taken along the lines VA-VA′ and VB-VB′, respectively, and illustrate the step following the step shown in FIGS. 6A and 6B; FIG. 8 is a layout view of the TFT array panel in the step following the step shown in FIGS. 7A and 7B; FIGS. 9A and 9B are sectional views of the TFT array panel shown in FIG. 8 taken along the lines IXA-IXA′ and IXB-IXB′, respectively; FIG. 10 is a layout view of the TFT array panel in the step following the step shown in FIGS. 9A and 9B; and FIGS. 11A and 11B are sectional views of the TFT array panel shown in FIG. 10 taken along the lines XIA-XIA′ and XIB-XIB′, respectively.

Two conductive films, a lower conductive film and an upper conductive film, are sputtered in sequence on an insulating substrate 110 such as transparent glass. The lower conductive film is preferably made of a material such as Al and Al alloy, and preferably has a thickness in the range of about 1,000-3,000 Å. The upper conductive film is preferably made of Mo or Mo alloy, and preferably has a thickness in the range of 500-1,000 Å.

Referring to FIGS. 4, 5A, and 5B, after forming a photoresist on the upper conductive film, the upper conductive film and the lower conductive film are patterned in sequence using the photoresist as an etch mask to form a plurality of gate lines 121 including a plurality of gate electrodes 124, and a plurality of storage electrode lines 131, and then the removal of the photoresist follows.

The patterning of the upper films 121q and 131q and the lower films 121p and 131p is performed by wet etching, preferably using an Al etchant including CH₃COOH, HNO₃, L₃PO₃, and remaining H₂O, which can etch both Al and Mo with inclined etch profiles.

Referring to FIGS. 6A and 6B, a gate insulating layer 140, an intrinsic a-Si layer 150, and an extrinsic a-Si layer 160 are sequentially deposited by CVD, such that the layers 140, 150, and 160 bear a thickness of about 1,500-5,000 Å, about 500-2,000 Å, and about 300-600 Å, respectively. A conductive layer 170 is deposited by sputtering, and a photoresist with the thickness of about 1-2 microns is coated on the conductive layer 170. The photoresist is exposed to light through an exposure mask (not shown) and developed to form a photoresist film 52, 54.

The developed photoresist film 52, 54 has a position-dependent thickness. The photoresist shown in FIGS. 6A and 6B includes a plurality of first to third portions with decreased thickness. The first portions located on areas A and the second portions located on areas C are indicated by reference numerals 52 and 54, respectively, and no reference numeral is assigned to the third portions located on areas B since they have substantially zero thickness so as to expose the underlying portions of the conductive layer 170. The thickness ratio of the second portions 54 to the first portions 52 is adjusted depending upon the process conditions in the subsequent process steps. It is preferable that the thickness of the second portions 54 be equal to or less than half of the thickness of the first portions 52, and in particular, equal to or less than 4,000 Å. At this time, the areas A correspond to the data lines 171 and the drain electrode 175, and the areas C correspond to the portions between the source electrode 173 and the drain electrode 175, and to the storage electrode lines 131, and the areas B are the remaining areas except for the areas A and C.

The position-dependent thickness of the photoresist is obtained by several techniques. For example, it can be achieved by providing translucent areas on the exposure mask as well as transparent areas and light blocking opaque areas. The translucent areas may have a slit pattern, a lattice pattern, or a thin film(s) with intermediate transmittance or intermediate thickness. When using a slit pattern, it is preferable that the width of the slits or the distance between the slits is smaller than the resolution of a light exposer used for the photolithography.

The different thickness of the photoresist 52, 54 allows selective etching of the underlying layers when using suitable process conditions. Therefore, a plurality of data lines 171 including a plurality of source electrodes 173, and a plurality of drain electrodes 175, as well as a plurality of ohmic contact stripes 161 including a plurality of projections 163, a plurality of ohmic contact islands 165, and a plurality of semiconductor stripes 151 including a plurality of projections 154 and semiconductor islands 157 are obtained as shown in FIGS. 8, 9A, and 9B by a series of etching steps.

For descriptive purposes, portions of the conductive layer 170, the extrinsic a-Si layer 160, and the intrinsic a-Si layer 150 on the areas A are called first portions, portions of the conductive layer 170, the extrinsic a-Si layer 160, and the intrinsic a-Si layer 150 on the areas C are called second portions, and portions of the conductive layer 170, the extrinsic a-Si layer 160, and the intrinsic a-Si layer 150 on the areas B are called third portions.

An exemplary sequence of forming such a structure is as follows:

(1) Removal of third portions of the conductive layer 170, the extrinsic a-Si layer 160, and the intrinsic a-Si layer 150 on the areas B;

(2) Removal of the second portions 54 of the photoresist;

(3) Removal of the second portions of the conductive layer 170 and the extrinsic a-Si layer 160 on the channel areas C; and

(4) Removal of the first portions 52 of the photoresist.

Another exemplary sequence is as follows:

(1) Removal of the third portions of the conductive layer 170;

(2) Removal of the second portions 54 of the photoresist;

(3) Removal of the third portions of the extrinsic a-Si layer 160 and the intrinsic a-Si layer 150;

(4) Removal of the second portions of the conductive layer 170;

(5) Removal of the first portions 52 of the photoresist; and

(6) Removal of the second portions of the extrinsic a-Si layer 160.

The second example is now described in detail.

Referring to FIGS. 7A and 7B, the exposed third portions of the conductive layer 170 on the remaining areas B are removed by wet etching or dry etching to expose the underlying third portions of the extrinsic a-Si layer 160. The Al-containing metal film is preferably wet etched, while the Mo-containing metal films can be etched both by a dry etch and a wet etch. The double-layered structure including Al and Mo may be simultaneously etched under the same etching condition.

Reference numeral 174 indicates conductors of the conductive layer 170 including the data lines 171 and the drain electrode 175 connected to each other and reference numeral 177 indicates conductors remained on the storage electrode lines 131. The conductors 174 and 177 are over-etched under the photoresist film 52,54, thereby making an under-cut structure.

Next, the third portions of the extrinsic a-Si layer 160 and the intrinsic a-Si layer 150 on the areas B are removed preferably by dry etching, and the second portions 54 of the photoresist are removed to expose the second portions of the conductors 174. The removal of the second portions 54 of the photoresist are performed either simultaneously with, or independent from, the removal of the third portions of the extrinsic a-Si layer 160 and of the intrinsic a-Si layer 150. Residue of the second portions 54 of the photoresist remaining on the areas C is removed by ashing.

The semiconductor stripes 151 are completed in this step, and reference numerals 164 and 167 indicate portions of the extrinsic a-Si layer 160 including the ohmic contact stripes and islands 161 and 165 connected to each other and disposed on the storage electrode lines 131, which are called “extrinsic semiconductor stripes.”

Referring to FIGS. 8, 9A, and 9B, the second portions of the conductors 174 and the extrinsic a-Si stripes 164 on the areas C, as well as the first portion 52 of the photoresist, are removed.

As shown in FIG. 9B, top portions of the projections 154 of the intrinsic semiconductor stripes 151 and islands 157 on the areas C may be removed to reduce thickness, and the first portions 52 of the photoresist are etched to a predetermined thickness.

In this way, each conductor 174 is divided into a data line 171 and a plurality of drain electrodes 175 to be completed, and each extrinsic semiconductor stripe 164 is divided into an ohmic contact stripe 161 and a plurality of ohmic contact islands 165 to be completed.

Referring to FIGS. 10, 11A, and 11B, a passivation layer 180 is formed by the CVD of a silicon nitride, by the coating of an acrylic organic insulating film, or by the PECVD of a low dielectric insulating material such as a-Si:C:O and a-Si:O:F having a low dielectric constant. Thereafter, the passivation layer 180 and the gate insulating layer 140 are photo-etched to form a plurality of contact holes 181, 182, and 185, and openings 187. At this time, the etch condition of the passivation layer 180 and the gate insulating layer 140 has high etch selectivity with the respect to the semiconductors 151 and 154. Accordingly, the semiconductor islands 157 exposed through the openings 187 prevent the gate insulating layer under the semiconductor islands 157 from etching. It is preferable that the boundary of the opening 187 is disposed within the boundary of the semiconductor islands 157 to prevent the storage electrode lines 131 from being exposed.

Finally, as shown in FIGS. 1-3, the semiconductor islands 157 exposed through openings 187 are etched to expose the gate insulating layer 140 on the storage electrode lines 131. Next, a plurality of pixel electrodes 190 and a plurality of contact assistants 81 and 82 are formed on the passivation layer 180 by sputtering and photo-etching an ITO or IZO layer. The etching of the IZO film may include wet etching using a Cr etchant, such as HNO₃/(NH₄)₂Ce(NO₃)₆/H₂O, which does not erode the exposed Al portions of the gate lines 121, the data lines 171, and the drain electrodes 175, through the contact holes 182, 181, and 185.

Since the manufacturing method of the TFT array panel according to an embodiment of the invention simultaneously forms the data lines 171, the drain electrodes 175, the semiconductors 151 and 154, and the ohmic contacts 161 and 165 using only one photolithography process, the manufacturing process is simplified. More specifically, a photolithography step is omitted relative to the current process.

In the manufacturing method according to the present invention, because the semiconductor islands 157 between the pixel electrodes 190 and the storage electrode lines 131 are removed, and the gate insulating layer 140 is used only as a dielectric of the storage capacitor, a uniform storage capacitance can be provided.

On the other hand, the wide viewing angle of the LCD can be realized by cutouts in the field-generating electrodes and protrusions on the field-generating electrodes. Since the cutouts and protrusions can determine the tilt directions of the LC molecules, the tilt directions can be distributed in several directions by using the cutouts and the protrusions such that the viewing angle is widened.

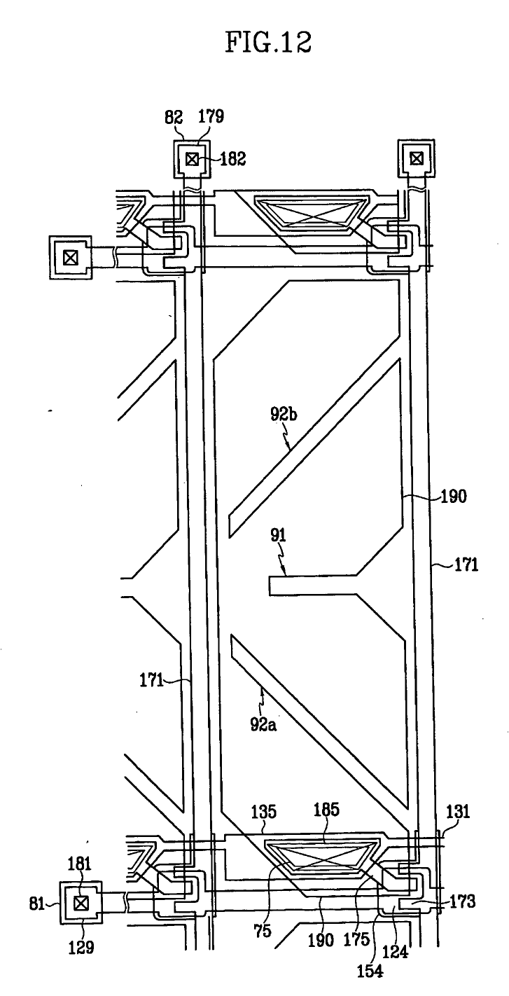

An LCD according to another embodiment of the present invention will be described in detail with reference to FIGS. 12-15.

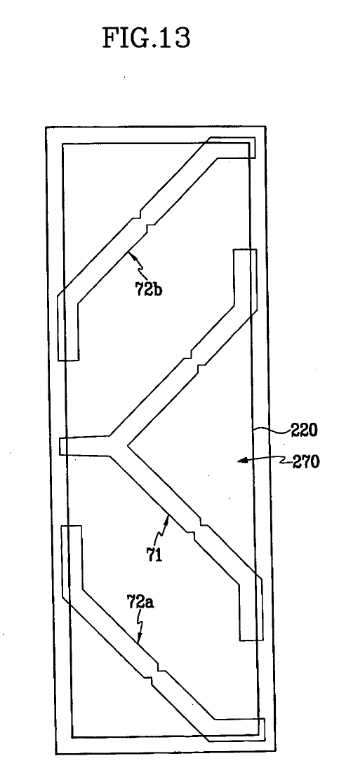

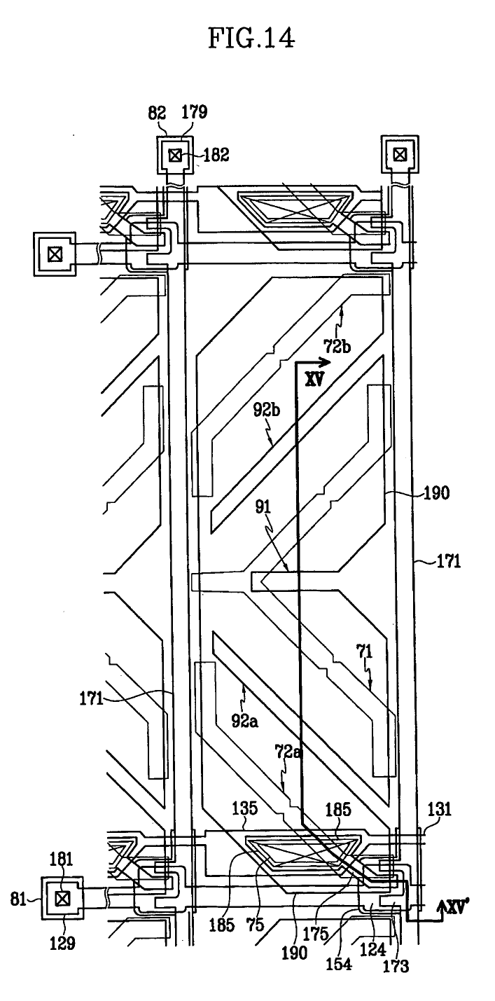

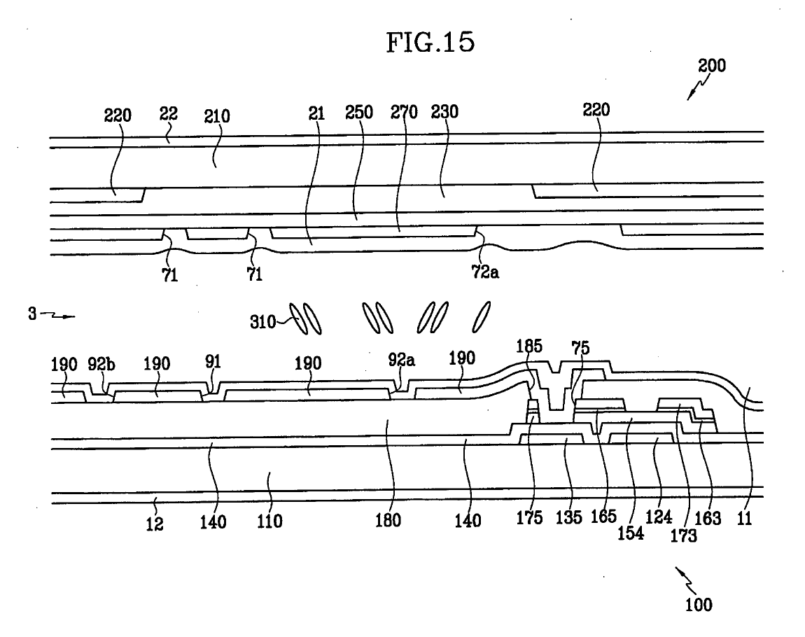

FIG. 12 is a layout view of a TFT array panel of an LCD according to another embodiment of the present invention; FIG. 13 is a layout view of a common electrode panel of an LCD according to an embodiment of the present invention; FIG. 14 is a layout view of an LCD including the TFT array panel shown in FIG. 12 and the common electrode panel shown in FIG. 13; and FIG. 15 is a sectional view of the LCD shown in FIG. 14 taken along the line XV-XV′.

An LCD according to an embodiment of the present invention includes a TFT array panel 100, a common electrode panel 200, and an LC layer 3 interposed between the panels 100 and 200 and containing a plurality of LC molecules 310 aligned substantially perpendicular to surfaces of the panels 100 and 200.

As shown in FIGS. 12-15, a layered structure of a TFT array panel of an LCD according to this embodiment is almost the same as that shown in FIGS. 1 to 3.

That is, a plurality of gate lines 121 including a plurality of gate electrodes 124 and a plurality of storage electrode lines 131 are formed on a substrate 110, and a gate insulating layer 140, a plurality of semiconductor stripes 151 including a plurality of projections 154, and a plurality of ohmic contact stripes 161 including a plurality of projections 163 and a plurality of ohmic contact islands 165 are sequentially formed thereon. A plurality of data lines 171 including a plurality of source electrodes 173 and a plurality of drain electrodes 175 are formed on the ohmic contacts 161 and 165, and a passivation layer 180 is formed thereon. A plurality of contact holes 182, 185, and 181 are provided at the passivation layer 180 and/or the gate insulating layer 140, and a plurality of pixel electrodes 190 and a plurality of contact assistants 81 and 82 are formed on the passivation layer 180.

Different from the TFT array panel shown in FIGS. 1 to 3, the TF array panel according to this embodiment provides a plurality of gate lines 121 including a plurality of projections forming a plurality of gate electrodes 124, and a plurality of storage electrode lines 131 having a plurality of projections forming a plurality of storage electrodes 135.

Each of the drain electrodes 175 extends upward/downward from an end portion and includes an expansion having a large area for contact with another layer and each of the source electrodes 173 is curved to partly enclose an end portion of the drain electrode 175. The expansion of the drain electrode 175 overlaps the storage electrode 135, and has an opening 75 exposing the gate insulating layer 140 on the storage electrode 135. The boundary of the drain electrode 175, which parallels the gate lines 121, parallels the boundary of the storage electrode 135.

A passivation layer 180 has a plurality of contact holes 185 exposing the openings 75 of the drain electrode 175 and the portions of the drain electrodes 175. The pixel electrode 190 is connected to the drain electrode 175 through the contact hole 185, and overlaps the storage electrode 135 via the gate insulating layer 140 through the opening 75.

In this embodiment, the contact hole 185 is disposed on the storage electrode 135 to connect the pixel electrode 190 to the drain electrode 175, but the drain electrode 175 and the opening 75 may be expanded larger than the storage electrode 135, like the opening 187 of FIG. 1.

Each pixel electrode 190 is chamfered at its left corners and the chamfered edges of the pixel electrode 190 make an angle of about 45 degrees with the gate lines 121.

Each pixel electrode 190 has a lower cutout 92a, a center cutout 91, and an upper cutout 92b, which partition the pixel electrode 190 into a plurality of partitions. The cutouts 91, 92a, and 92b substantially have an inversion symmetry with respect to an imaginary transverse line bisecting the pixel electrode 190.

The lower and the upper cutouts 92a and 92b obliquely extend from a right edge of the pixel electrode 190 near an upper right corner and a lower right corner, respectively, to approximately a center of a left edge of the pixel electrode 190. The lower and the upper cutouts 92a and 92b are disposed at lower and upper halves of the pixel electrode 190, respectively, which can be divided by an imaginary transverse line. The lower and the upper cutouts 92a and 92b make an angle of about 45 degrees to the gate lines 121, and they extend substantially perpendicular to each other.

The center cutout 91 extends along the imaginary transverse line and has an inlet from the right edge of the pixel electrode 190, which has a pair of inclined edges substantially parallel to the lower cutout 92a and the upper cutout 92b, respectively.

Accordingly, the lower half of the pixel electrode 190 is partitioned into two lower partitions by the lower cutout 92a and the upper half of the pixel electrode 190 is also partitioned into two upper partitions by the upper cutout 92b. The number of partitions or the number of cutouts is varied depending on design factors, such as the size of pixels, the ratio of the transverse edges and the longitudinal edges of the pixel electrodes, the type and characteristics of the liquid crystal layer 3, and so on.

The description of the common electrode panel 200 follows with reference to FIGS. 13-15.

A light blocking member 220, called a black matrix, for preventing light leakage is formed on an insulating substrate 210, such as transparent glass.

The light blocking member 220 may include a plurality of openings that face the pixel electrodes 190 and may have substantially the same planar shape as the pixel electrodes 190. Otherwise, the light blocking member 220 may include linear portions corresponding to the data lines 171 and other portions corresponding to the TFTs.

A plurality of color filters 230 are formed on the substrate 210 and they are disposed substantially in the areas enclosed by the light blocking member 220. The color filters 230 may extend substantially in the longitudinal direction along the pixel electrodes 190. The color filters 230 may represent one of the primary colors, i.e., red, green, and blue.

An overcoat 250, for preventing the color filters 230 from being exposed and for providing a flat surface, is formed on the color filters 230 and the light blocking member 220.

A common electrode 270, preferably made of a transparent conductive material such as ITO and IZO, is formed on the overcoat 250.

The common electrode 270 has a plurality of sets of cutouts 71, 72a, 72b.

A set of cutouts 71-72b faces a pixel electrode 190 and includes a lower cutout 72a, a center cutout 71, and an upper cutout 72b. Each of the cutouts 71-72b is disposed between adjacent cutouts 91-92b of the pixel electrode 190 or between the lower or upper cutouts 92a or 92b and a chamfered edge of the pixel electrode 190. In addition, each of the cutouts 71-72b has at least an oblique portion extending parallel to the lower cutout 92a or the upper cutout 92b of the pixel electrode 190, and the distances between two adjacent cutouts 71-72b and 91-92b, the oblique portions thereof, the oblique edges thereof, and the chamfered edges of the pixel electrode 190, which are parallel to each other, are substantially the same. The cutouts 71-72b have substantially an inversion symmetry with respect to the above-described transverse line bisecting the pixel electrode 190.

Each of the lower and upper cutouts 72a and 72b includes an oblique portion extending approximately from a left edge of the pixel electrode 190 to approximately a lower or upper edge of the pixel electrode 190, and transverse and longitudinal portions extend from respective ends of the oblique portion along edges of the pixel electrode 190, overlapping the edges of the pixel electrode 190, and make obtuse angles with the oblique portion.

The center cutout 71 includes a central transverse portion extending approximately from the center of the left edge of the pixel electrode 190, a pair of oblique portions extending from an end of the central transverse portion approximately to the right edge of the pixel electrode and making obtuse angles with the central transverse portion, and a pair of terminal longitudinal portions extending from the ends of the respective oblique portions along the right edge of the pixel electrode 190, overlapping the right edge of the pixel electrode 190, and making obtuse angles with the respective oblique portions.

The number of the cutouts 71-72b may be varied depending on the design factors, and the light blocking member 220 may also overlap the cutouts 71-72b to block light leakage through the cutouts 71-72b.

Alignment layers 11 and 21 that may be homeotropic are coated on inner surfaces of the panels 100 and 200, and polarizers 12 and 22 are provided on outer surfaces of the panels 100 and 200 such that their polarization axes may be crossed and one of the transmissive axes may be parallel to the gate lines 121. One of the polarizers may be omitted when the LCD is a reflective LCD.

The LCD may further include at least one retardation film (not shown) for compensating the retardation of the LC layer 3. The retardation film has birefringence and gives a retardation opposite to that given by the LC layer 3. The retardation film may include a uniaxial or biaxial optical compensation film, in particular, a negative uniaxial compensation film.

The LCD may further include a backlight unit (not shown) supplying light to the LC layer 3 through the polarizers 12 and 22, the retardation film, and the panels 100 and 200.

It is preferable that the LC layer 3 has negative dielectric anisotropy and it is subjected to a vertical alignment where the LC molecules 310 in the LC layer 3 are aligned such that their long axes are substantially perpendicular to the surfaces of the panels 100 and 200 in the absence of an electric field.

As shown in FIG. 14, a set of cutouts 91-92b and 71-72b divides a pixel electrode 190 into a plurality of sub-areas and each sub-area has two major edges.

Upon application of the common voltage to the common electrode 270 and a data voltage to the pixel electrodes 190, an electric field substantially perpendicular to the surfaces of the panels 100 and 200 is generated. The LC molecules 310 tend to change their orientations in response to the electric field such that their long axes are perpendicular to the field direction.

The cutouts 91-92b and 71-72b of the electrodes 190 and 270 and the edges of the pixel electrodes 190 distort the electric field to have a horizontal component that is substantially perpendicular to the edges of the cutouts 91-92b and 71-72b and the edges of the pixel electrodes 190. Accordingly, the LC molecules on each sub-area are tilt in a direction by the horizontal component and the azimuthal distribution of the tilt directions are localized to four directions, thereby increasing the viewing angle of the LCD.

It is preferable that the width of the cutouts 91-92b and 71-72b are in the range of 9-12 μm.

At least one of the cutouts 91-92b and 71-72b can be substituted with protrusions (not shown) or depressions (not shown). The protrusions are preferably made of organic or inorganic material and disposed on or under the field-generating electrodes 190 or 270, and it is preferable that the width of the protrusions is in the range of 5-10 μm.

The shapes and the arrangements of the cutouts 91-92b and 71-72b may be modified.

Since the tilt directions of all domains make an angle of about 45 degrees with the gate lines 121, which are parallel to or perpendicular to the edges of the panels 100 and 200, and the 45-degree intersection of the tilt directions and the transmissive axes of the polarizers 12 and 22 gives maximum transmittance, the polarizers 12 and 22 can be attached such that the transmissive axes of the polarizers 12 and 22 are parallel to or perpendicular to the edges of the panels 100 and 200, which reduces the production cost.

Many of the above-described features of the LCD according to the previous embodiment may be appropriate to the TFT array panel shown in FIGS. 12-15.

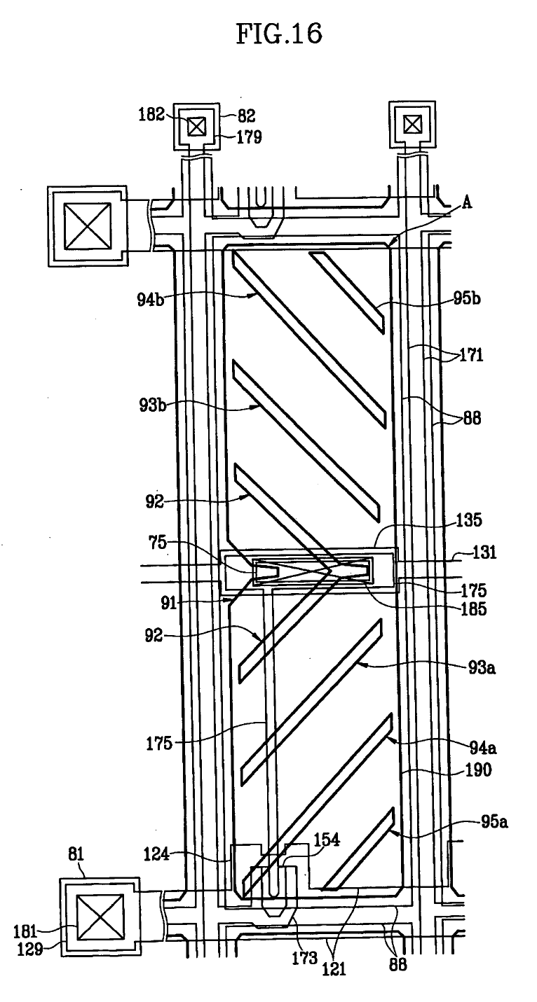

An LCD according to another embodiment of the present invention will be described in detail with reference to FIGS. 16-19.

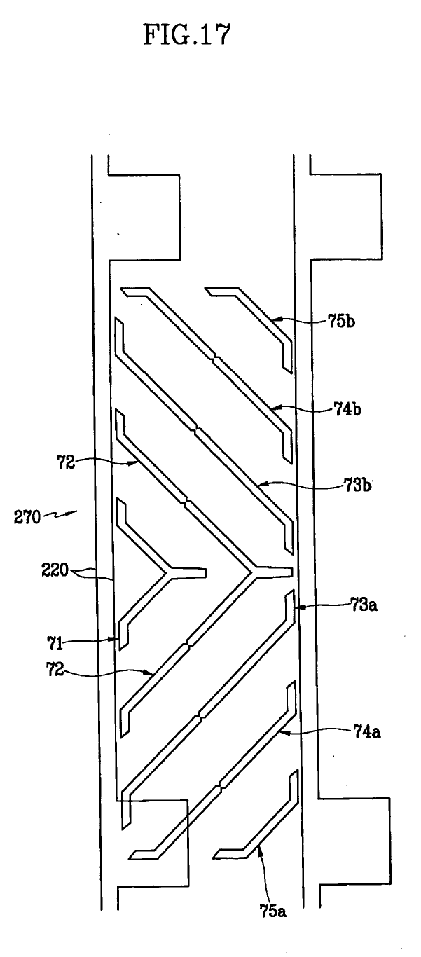

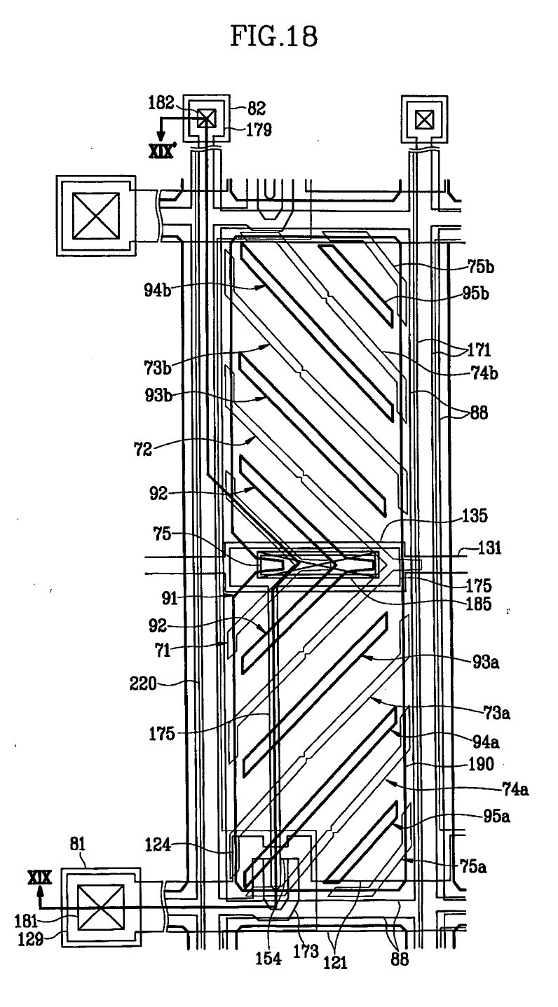

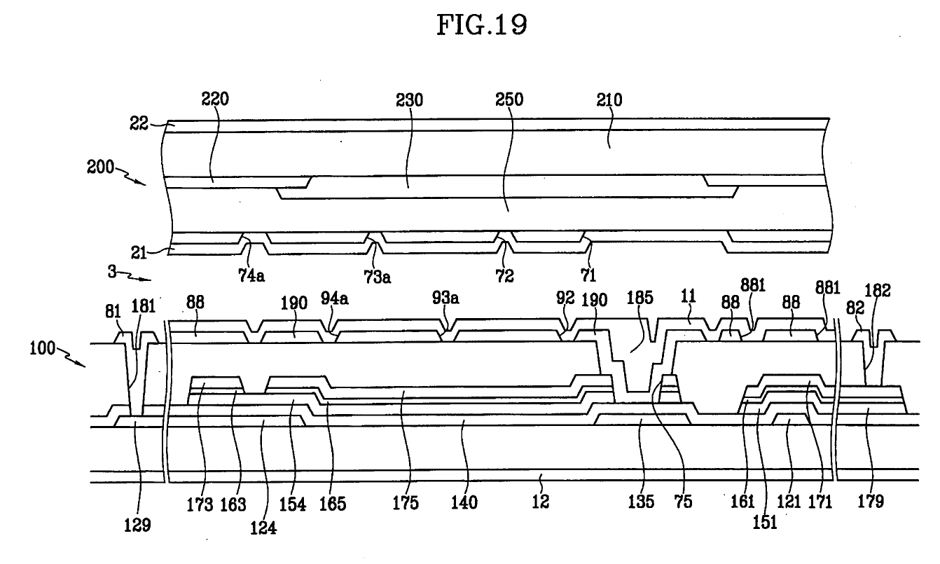

FIG. 16 is a layout view of a TFT array panel of an LCD according to another embodiment of the present invention; FIG. 17 is a layout view of a common electrode panel of an LCD according to an embodiment of the present invention; FIG. 18 is a layout view of an LCD including the TFT array panel shown in FIG. 16 and the common electrode panel shown in FIG. 17; and FIG. 19 is a sectional view of the LCD shown in FIG. 18 taken along the line XIX-XIX′.

Referring to FIGS. 16-19, an LCD according to this embodiment also includes a TFT array panel 100, a common electrode panel 200, an LC layer 3 interposed between the panels 100 and 200, and a pair of polarizers 12 and 22 attached on outer surfaces of the panels 100 and 200.

Layered structures of the panels 100 and 200 according to this embodiment are almost the same as those shown in FIGS. 1/4.

Regarding the TFT array panel 100, a plurality of gate lines 121 including gate electrodes 124 and end portions 129 and a plurality of storage electrode lines 131 including storage electrodes 135 are formed on a substrate 110, and a gate insulating layer 140, a plurality of semiconductor stripes 151 including projections 154, and a plurality of ohmic contact stripes 161 including projections 163 and a plurality of ohmic contact islands 165 are sequentially formed thereon. A plurality of data lines 171 including source electrodes 173 and end portions 179, and a plurality of drain electrodes 175 having openings 75 on the storage electrodes 135 are formed on the ohmic contacts 161 and 165, and a passivation layer 180 is formed thereon. A plurality of contact holes 181, 182, and 185 are provided at the passivation layer 180 and the gate insulating layer 140. A plurality of pixel electrodes 190, and a plurality of contact assistants 81 and 82 are formed on the passivation layer 180, and an alignment layer 11 is coated thereon.

Regarding the common electrode panel 200, a light blocking member 220 having a plurality of openings, a plurality of color filters 230, an overcoat 250, a common electrode 270, and an alignment layer 21 are formed on an insulating substrate 210.

Each of the pixel electrodes 190 has four chamfered corners A forming oblique edges, and a plurality of shielding electrodes 88 are formed at the same layer as the pixel electrode 190.

The length of the oblique edges is preferably equal to about four to ten microns, and in particular, it is preferably larger than the resolution of a light exposer used in a photolithography step for forming the pixel electrodes 190 and the shielding electrodes 88. Accordingly, the probability that conductive remnants remain near the corners A of the pixel electrodes 190 is significantly reduced to prevent a short circuit between the pixel electrodes 190 and the shielding electrodes 88 while allowing the pixel electrodes 190 and the shielding electrodes 88 to be close to each other.

Furthermore, when the pixel electrodes 190 and the shielding electrodes 88 are short-circuited near the corners A of the pixel electrodes 190, the short-circuited position can be easily detected using a low magnification optical device and the short-circuit can be easily repaired using a laser beam since the distance between the shielding electrodes 88 and the pixel electrodes 190 is large at the corners A.

The shielding electrodes 88 have a plurality of horizontal portions extending along the gate lines 121 and a plurality of longitudinal portions extending along the data lines 171. It is preferable that the horizontal portions are narrower than the gate lines 121 and the longitude portions are wider than the data lines 171.

The shielding electrodes 88 are supplied with the common voltage and they may be connected to the storage electrode lines 131 through contact holes (not shown) penetrating the gate insulating layer 140 and the passivation layer 180 or connected to short points (not shown) where the common voltage is transmitted from the TFT array panel 100 to the common electrode panel 200. The distance between the shielding electrodes 88 and the pixel electrodes 190 is preferably minimized to decrease the aperture ratio.

The shielding electrodes 88 supplied with the common voltage can block electric fields generated between the pixel electrodes 190 and the data lines 171 and between the common electrode 270 and the data lines 171 such that the distortion of the voltage of the pixel electrodes 190 and the signal delay of the data voltages transmitted by the data lines 171 are reduced.

Furthermore, since the pixel electrodes 190 are required to be spaced apart from the shielding electrodes 88 for preventing the short therebetween, the pixel electrodes 190 become farther from the data lines 171 such that the parasitic capacitance therebetween becomes reduced. Moreover, since the permittivity of the LC layer 3 is larger than that of the passivation layer 180, the parasitic capacitance between the data lines 171 and the shielding electrodes 88 is reduced, compared with that between the data lines 171 and the common electrode 270 without the shielding electrodes 88.

In addition, the distance between the pixel electrodes 190 and the shielding electrodes 88 can be uniformly maintained since they are made of the same layer and thus the parasitic capacitance therebetween can be made uniform. Although the parasitic capacitance between the pixel electrodes 190 and the data lines 171 may still vary between exposure areas divided in a divisional exposure process, the total parasitic capacitance can be nearly uniform since the parasitic capacitance between the pixel electrodes 190 and the data lines 171 is relatively reduced.

In addition, the arrangements and the shapes of cutouts 91, 92, 93a, 93b, 94a, 94b, 95a, and 95b of the pixel electrodes 190 and the cutouts 71, 72, 73a, 73b, 74a, 74b, 75a, and 75b of the common electrode 270 are slightly different. In particular, the cutouts 71, 72, 73a, 73b, 74a, 74b, 75a, and 75b of the common electrode 270 have notches for controlling the alignments of the LC molecules 310 in the cutouts 71, 72, 73a, 73b, 74a, 74b, 75a, and 75b.

The light blocking member 220 includes linear portions corresponding to the data lines 171 and other portions corresponding to the TFTs.

In the meantime, the magnitude of the electric field between the common electrode 270 and the shielding electrodes 88 is nearly zero since the common electrode 270 and the shielding electrodes 88 are supplied with the same voltage, i.e., the common voltage. Therefore, the LC molecules 310 disposed between the common electrode 270 and the shielding electrodes 88 maintain their initially vertical alignments such that light incident on those regions may be blocked rather than transmitted.

As above described, this invention simplifies the manufacturing process by patterning the layers through a single photolithography process using a photoresist including middle thickness.

Also, because the gate insulating layer as a dielectric of the storage capacitor is only disposed by removing a semiconductor between the pixel electrode and the storage electrode lines, a uniform storage capacitance may be provided, and the storage capacitance may be maximized in the optimized area. Accordingly, the characteristics of the LCD may be enhanced and an aperture ratio of the pixels may be increased.

While the present invention has been described in detail with reference to the preferred embodiments, those skilled in the art will appreciate that various modifications and substitutions can be made thereto without departing from the spirit and scope of the present invention as set forth in the appended claims.

1. A thin film transistor array panel comprising:
a gate line formed on an insulating substrate and having a gate electrode;
a storage electrode line on the insulating substrate;
a gate insulating layer on the gate line and the storage electrode line;
a first semiconductor on the gate insulating layer;
a data line and a drain electrode formed on the first semiconductor, separate from the each other, and over the gate electrode;
a passivation layer formed on the first semiconductor layer and having a contact hole exposing the drain electrode and an opening exposing the gate insulating layer on the storage electrode; and
a pixel electrode connected to the drain electrode through the contact hole and overlapping the storage electrode through the opening.

2. The thin film transistor array panel of claim 1, wherein the first semiconductor, except for the portion on the gate electrode, has the same shape as the data line and the drain electrode.

3. The thin film transistor array panel of claim 1, further comprising
a second semiconductor made at the same layer as the first semiconductor, wherein the opening extends to the second semiconductor.

4. The thin film transistor array panel of claim 3, wherein the opening is a hole that extends through the second semiconductor.

5. The thin film transistor array panel of claim 1, wherein the contact hole overlaps the opening.

6. The thin film transistor array panel of claim 5, wherein the opening is located inside the contact hole.

7. The thin film transistor array panel of claim 6, wherein the opening extends into the drain electrode.

8. The thin film transistor array panel of claim 7, wherein the storage electrode line is spaced apart from the gate line.

9. A method of manufacturing a thin film transistor array panel, the method comprising:
forming a gate line and a storage electrode line;
forming a gate insulating layer covering the gate line and the storage electrode line;
forming a first semiconductor and a second semiconductor overlapping the storage electrode line on the gate insulating layer;
forming a data line having a source electrode and a drain electrode on the first semiconductor;
forming a passivation layer having a contact hole exposing the drain electrode and an opening exposing the second semiconductor;
removing the second semiconductor exposed through the opening; and
forming a pixel electrode connected to the drain electrode through the contact hole,
wherein the first and second semiconductors, and the data line and the drain electrode are formed by photolithography using one photoresist film as an etch mask.

10. The method of claim 9, wherein the photoresist film includes a first portion corresponding to a channel area on the portion between the source electrode and the drain electrode, a storage area corresponding to a portion of the storage electrode line, and a second portion corresponding to a wire area on the data line and the drain electrode.

11. The method of claim 10, wherein the photoresist film is formed by photolithography using one mask.

12. The method of claim 9, further comprising:
forming an ohmic contact layer between the first and second semiconductors and the data line and drain electrode.

13. The method of claim 12, wherein the formation of the data line and the drain electrode, the ohmic contact layer, and the first and second semiconductors comprises:
depositing a silicon layer, a doped silicon layer, and a conductor layer;
forming a photoresist film including a first portion corresponding to a channel area on a portion between the source electrode and the drain electrode, a storage area corresponding to a portion of the storage electrode line, and a second portion corresponding to a wire area on the data line and the drain electrode;
etching the conductor layer corresponding to a remaining area except for the storage, wire, and channel areas;
etching the silicon layer and the doped silicon layer on the remaining area;
removing the first portion to expose the conductor layer on the storage and the channel areas;
etching the conductor layer and the doped silicon layer on the storage and channel areas; and
removing the second portion.
